(19) United States
(12) Patent Application Publication
(10) Pub. No.: US 2015/0039264 A1
(43) Pub. Date: Feb. 5, 2015

(54) DEVICE FOR CALCULATING ROUND-TRIP TIME OF MEMORY TEST USING PROGRAMMABLE LOGIC

(71) Applicant: UNITEST INC., Gyeonggi-do (KR)

(72) Inventor: Ho Sang YOU, Seoul (KR)

(73) Assignee: UNITEST INC., Gyeonggi-do (KR)

(21) Appl. No.: 14/446,438

(22) Filed: Jul. 30, 2014

(30) Foreign Application Priority Data
Jul. 31, 2013 (KR) 10-2013-0090907

(51) Int. Cl. G01R 31/26

(52) U.S. Cl. CPC G01R 31/2607
USPC 702/176

(57) ABSTRACT

A device for calculating round-trip time of a memory test using a programmable logic includes a pattern generation part including two pairs of input/output (IO) pins to generate a pattern signal for testing, and receiving a feedback signal through bidirectional buses from IO lines; two pairs of bidirectional buses for relaying a signal between the pattern generation part and a programmable logic part; and a programmable logic part for transmitting the pattern signal to the IO lines through the bidirectional buses and transmitting the feedback signal to the bidirectional buses from the IO lines, and including a multiplexer for crossing a signal connection direction upon calculation of the feedback signal, wherein the pattern generation part measures an input time of the feedback signal based on an output time of the pattern signal, thus calculating the round-trip time of the signal.

### BACKGROUND OF THE INVENTION

1. Field of the Invention

The present invention relates to a device for calculating round-trip time of a test of a semiconductor memory test device, and more particularly to a device for calculating round-trip time of a memory test, wherein even when a memory device as a device under test (DUT) is absent and a physical bus line is not additionally provided, the round-trip time of a test signal from a pattern generator to DUT may be calculated.

2. Description of the Related Art

Regarding semiconductor test devices, a plurality patents including Korean Patent Application Publication No. 10-2009-0127689 (hereinafter, referred to as “cited reference”) has been applied and laid-open.

In this cited reference, the memory test device includes a general register for calculation using a predetermined general command; an extension register having capacity greater than that of the general register and for calculation using a predetermined extension command; and a controller for writing a predetermined test pattern to an external memory using the extension command, reading the test pattern written to the memory, determining whether the written test pattern and the read test pattern are matched with each other, and determining whether the memory is faulty or not using the general command.

In conventional semiconductor test devices including cited reference, DUT is electrically coupled with a pattern generator for testing thereof.

Upon semiconductor testing, a plurality of memory devices (DUTs) is dependently connected to a single output to increase mass productivity. As such, the capacity of the load terminals may increase, making it impossible to execute fast testing.

With the goal of solving such problems, as illustrated in FIG. 1, a programmable logic is adopted to reduce FAN out, thus resolving simultaneous measurement position and speed issues.

FIG. 1 illustrates a conventional memory test device using a programmable logic. As illustrated in this drawing, data output from the pattern generator 1 is sent to and received from final DUT 5 through a bidirectional bus 4 after FAN out by a programmable logic device 3 through a bidirectional bus 2. In contrast, when the data is read from the DUT, procedures flow in the reverse sequence as above, and thus data reaches the pattern generator.

However, because the signal is unidirectionally sent upon recording and reading by the bidirectional buses from the programmable logic to the DUT, a data arrival time upon reading the data to the DUT from the pattern generator cannot be detected in the absence of the DUT.

When the data arrival time is not detected in this way, it has to be found out using an additional proofreading process. Further, when the contents of the programmable logic device are modified in bulk or in part, the previous determination time cannot be used.

### SUMMARY OF THE INVENTION

Accordingly, the present invention has been made keeping in mind the above problems occurring in the prior art, and an object of the present invention is to provide a device for calculating the round-trip time of a test signal from a pattern generator to DUT even without the additional use of a physical bus line in the absence of the DUT.

In order to accomplish the above object, the present invention provides a device for calculating round-trip time of a memory test using a programmable logic, comprising: a pattern generation part including two pairs of input-output (IO) pins to generate a pattern signal for testing and receive a feedback signal from IO lines through bidirectional buses; two pairs of bidirectional buses for relaying a signal between the pattern generation part and a programmable logic part; and a programmable logic part for transmitting the pattern signal to the IO lines through the bidirectional buses and transmitting the feedback signal from the IO lines to the bidirectional buses, and including a multiplexer for crossing a signal connection direction upon calculation of the feedback signal, wherein the pattern generation part may measure an input time of the feedback signal based on an output time of the pattern signal, thus calculating the round-trip time of the signal.

Of the bidirectional buses, a first bidirectional bus may transmit the pattern signal from the pattern generation part to the programmable logic part, and a second bidirectional bus may transmit the feedback signal from the programmable logic part to the pattern generation part.

The programmable logic part may comprise: two pairs of first connection IO pins connected to the bidirectional buses so that the pattern signal is transmitted to the multiplexer through the bidirectional buses or the feedback signal from the IO lines is transmitted to the bidirectional buses through the multiplexer; the multiplexer connected to two pairs of the first connection IO pins and two pairs of second connection IO pins linked with IO lines and configured to cross a signal connection direction to the first connection IO pins upon calculation of the feedback signal; and two pairs of the second connection IO pins linked with the IO lines so that the pattern signal from the multiplexer is transmitted to the IO lines or the feedback signal from the IO lines is transmitted to the multiplexer.

According to the present invention, even when a memory device as DUT is absent and a physical bus line is not additionally provided, the round-trip time of a test signal from a pattern generator to DUT can be effectively calculated.

Also according to the present invention, temporal position information of the DUT can be found out, thus effectively obtaining a skew difference per data pin.

### BRIEF DESCRIPTION OF THE DRAWINGS

The above and other objects, features and advantages of the present invention will be more clearly understood from the following detailed description taken in conjunction with the accompanying drawings, in which:

FIG. 1 illustrates a conventional memory test device using a programmable logic;

FIG. 2 illustrates a device for calculating the round-trip time of a memory test using a programmable logic which shows the connection direction of a multiplexer upon ordinary testing according to the present invention; and

FIG. 3 illustrates a device for calculating the round-trip time of a memory test using a programmable logic which shows the connection direction of a multiplexer upon calculation of the round-trip time depending on the feedback for IO lines according to the present invention.

### DESCRIPTION OF SPECIFIC EMBODIMENTS

Hereinafter, a detailed description will be given of the present invention with reference to the appended drawings. In the following description, it is noted that, when the detailed description of known techniques related with the present invention may make the gist of the present invention unclear, a detailed description thereof will be omitted.

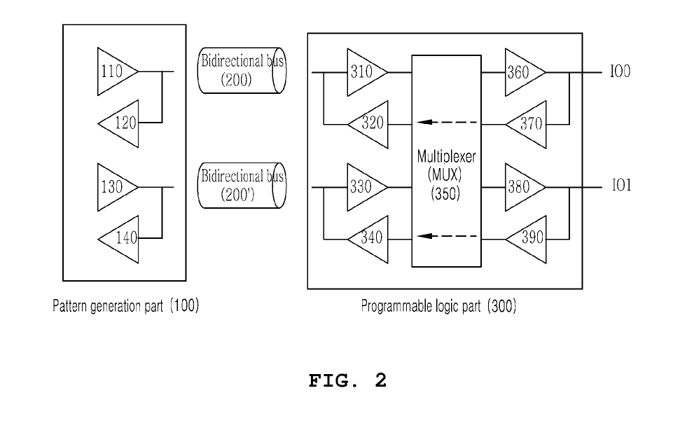

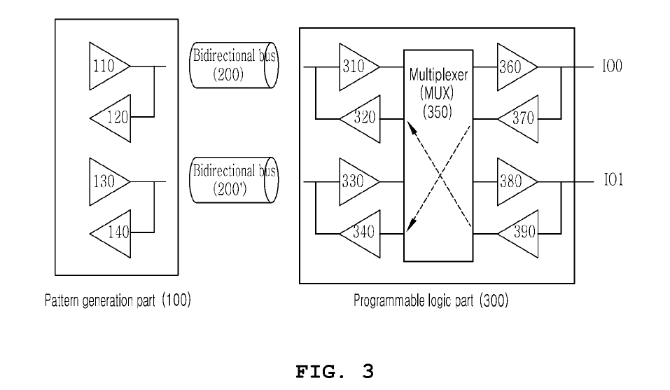

According to the present invention, a device for calculating the round-trip time of a memory test using a programmable logic is described with reference to FIGS. 2 and 3.

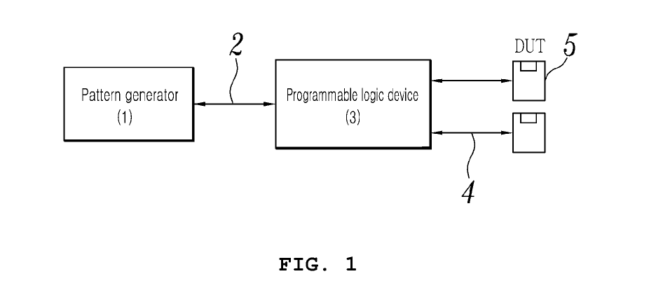

In a conventional bidirectional bus 200 as illustrated in FIG. 1, a recording path is different from a reading path in a programmable logic. Upon ordinary testing as illustrated in FIG. 2, the connection of a multiplexer of a programmable logic part 300 depends on the direction of flow of data in each IO line.

FIG. 3 illustrates a device for calculating the round-trip time of a memory test using a programmable logic according to the present invention, including a pattern generation part 100, bidirectional buses 200, 200′ and a programmable logic part 300.

The pattern generation part 100 generates a pattern signal for testing, and receives a feedback signal from IO lines IO0, IO1 through the bidirectional buses 200, 200′. As such, the pattern generation part 100 has two pairs of IO pins 110, 120, 130, 140.

Accordingly, the pattern generation part 100 functions to calculate the round-trip time of a signal by measuring the input time of the feedback signal based on the output time of the pattern signal from the IO pins.

The bidirectional buses 200, 200′ are provided in the form of two pairs, and relay the signal between the pattern generation part 100 and the programmable logic part 300.

Specifically, the first bidirectional bus 200 transmits the pattern signal from the pattern generation part 100 to the programmable logic part 300, and the second bidirectional bus 200′ transmits the feedback signal from the programmable logic part 300 to the pattern generation part 100.

The first and the second bidirectional bus 200, 200′ are connected to the pattern generation part 100 and the programmable logic part 300, so that IO directions may be set.

The programmable logic part 300 transmits the pattern signal to the IO lines IO0, IO1 through the bidirectional buses 200, 200′, and also transmits the feedback signal to the bidirectional buses 200, 200′ from the IO lines IO0, IO1. As such, upon calculation of the feedback signal, the multiplexer 350 may function to cross the signal connection direction. As illustrated in FIG. 3, the first connection IO pins 310, 320, 330, 340, the multiplexer 350 and the second connection IO pins 360, 370, 380, 390 are provided.

Specifically, the first connection IO pins 310, 320, 330, 340 are connected to the bidirectional buses 200, 200′ so as to transmit the pattern signal to the multiplexer 350 through the bidirectional buses 200, 200′ or to transmit the feedback signal to the bidirectional buses 200, 200′ through the multiplexer 350 from the IO lines IO0, IO1.

The multiplexer 350 is connected to two pairs of first connection IO pins 310, 320, 330, 340 and two pairs of second connection IO pins 360, 370, 380, 390 linked with the IO lines IO0, IO1, and functions to cross the signal connection direction to the first connection IO pins upon calculation of the feedback signal.

The second connection IO pins 360, 370, 380, 390 are linked with the IO lines IO0, IO1, so that the pattern signal is transmitted to the IO lines IO0, IO1 through the multiplexer 350 or the feedback signal is transmitted to the multiplexer 350 from the IO lines IO0, IO1.

As illustrated in FIG. 2, upon ordinary testing, the signal connection direction of the multiplexer 350 is matched with a typical flow direction. When measuring the feedback time, as illustrated in FIG. 3, the signal connection direction is crossed to the other group of connection IO pins by the multiplexer 350.

The IO pins 110, 120 of the pattern generation part 100, the first bidirectional bus 210, the first connection IO pins 310, 320, and the second connection IO pins 360, 370 are set to one group, whereas the IO pins 130, 140 of the pattern generation part 100, the second bidirectional bus 220, the first connection IO pins 330, 340 and the second connection IO pins 380, 390 are set to the other group. In this case, the signal connection direction is set by the multiplexer 350 so that the input of the pattern signal and the output of the feedback signal are carried out in the different groups.

Using the device for calculating the round-trip time of the memory test using the programmable logic, the calculation of the round-trip time depending on the feedback for the IO lines upon ordinary testing is described below.

As illustrated in FIG. 2, upon ordinary testing of the IO line IO0, the IO pin 110 of the pattern generation part 100 outputs the pattern signal, and the first bidirectional bus 200 relays the output pattern signal. Then, the first connection IO pin 310 of the programmable logic part 300 transmits the relayed pattern signal to the multiplexer 350, and the multiplexer 350 transmits the pattern signal to the IO line IO0 through the second connection IO pin 360.

Subsequently, the second connection IO pin 370 outputs the feedback signal, and the multiplexer 350 transmits the output feedback signal to the first connection IO pin 320. Then, the first connection IO pin 320 transmits the feedback signal to the first bidirectional bus 200, and the IO pin 120 of the pattern generation part 100 outputs the feedback signal.

In a specific aspect of the present invention, when the round-trip time depending on the feedback for the IO line IO0 is calculated, as illustrated in FIG. 3, the IO pin 110 of the pattern generation part 100 outputs the pattern signal, and the first bidirectional bus 200 relays the output pattern signal. Then, the first connection IO pin 310 of the programmable logic part 300 transmits the relayed pattern signal to the multiplexer 350, and the multiplexer 350 transmits the pattern signal to the IO line IO0 through the second connection IO pin 360.

Subsequently, the second connection IO pin 370 outputs the feedback signal, and the multiplexer 350 transmits the output feedback signal to the first connection IO pin 340. Then, the first connection IO pin 340 transmits the feedback signal to the second bidirectional bus 200′, and the IO pin 140 of the pattern generation part 100 outputs the feedback signal.

Finally, when the input time of the feedback signal to the IO pin 140 is measured based on the output time of the pattern signal from the IO pin 110 of the pattern generation part 100, the round-trip time of the signal for the IO line IO0 may be calculated.

Likewise, when the round-trip time of the signal for the IO line IO1 is calculated, the pattern signal is transmitted to the IO pin 130 of the pattern generation part 100=>the second bidirectional bus 200′=>the first connection IO pin 330=>the multiplexer 350=>the second connection IO pin 380=>the IO line IO1, and the feedback signal is transmitted to the second connection IO pin 390=>the multiplexer 350=>the first connection IO pin 320=>the first bidirectional bus 200=>the IO pin 120 of the pattern generation part 100.

The device for calculating the round-trip time of the memory test using the programmable logic having the aforementioned constructions and functions according to the present invention is spatially and economically favorable in terms of calculating the round-trip time of the signal in the DUT without extension of an original physical bus line connected for test purposes using an additional signal line, and enables temporal self-correction without the use of the DUT.

Further, the obtained time may be directly detected even when the contents of the programmable logic are modified, and based on the resulting time, temporal correction may be implemented in the pattern generator, thus achieving accurate testing.

Although the embodiments of the present invention have been disclosed for illustrative purposes, those skilled in the art will appreciate that a variety of different variations and modifications are possible, without departing from the scope and spirit of the invention as disclosed in the accompanying claims. Accordingly, such variations and modifications should also be understood as falling within the scope of the present invention.

What is claimed is:

1. A device for calculating round-trip time of a memory test using a programmable logic, comprising:
a pattern generation part including two pairs of input-output (IO) pins to generate a pattern signal for testing and receive a feedback signal from IO lines through bidirectional buses;
two pairs of bidirectional buses for relaying a signal between the pattern generation part and a programmable logic part; and
the programmable logic part for transmitting the pattern signal to the IO lines through the bidirectional buses and transmitting the feedback signal from the IO lines to the bidirectional buses, and including a multiplexer for crossing a signal connection direction upon calculation of the feedback signal,
wherein the pattern generation part may measure an input time of the feedback signal based on an output time of the pattern signal, thus calculating the round-trip time of the signal.

2. The device of claim 1, wherein of the bidirectional buses, a first bidirectional bus transmits the pattern signal from the pattern generation part to the programmable logic part, and a second bidirectional bus transmits the feedback signal from the programmable logic part to the pattern generation part.

3. The device of claim 1, wherein the programmable logic part comprises:
two pairs of first connection IO pins connected to the bidirectional buses so that the pattern signal is transmitted to the multiplexer through the bidirectional buses or the feedback signal from the IO lines is transmitted to the bidirectional buses through the multiplexer;
the multiplexer connected to two pairs of the first connection IO pins and two pairs of second connection IO pins linked with the IO lines and configured to cross a signal connection direction to the first connection IO pins upon calculation of the feedback signal; and
two pairs of the second connection IO pins linked with the IO lines so that the pattern signal from the multiplexer is transmitted to the IO lines or the feedback signal from the IO lines is transmitted to the multiplexer.
